(19) United States
(12) Patent Application Publication
(10) Pub. No.: US 2005/0189952 A1
(43) Pub. Date: Sep. 1, 2005

(54) Ratation angle sensor

(75) Inventors: Takashi Ejima, Handa-city (JP); Yasuaki Makino, Okazaki-city (JP); Shigenori Yamauchi, Nisshin-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/061,473

(22) Filed: Feb. 22, 2005

(30) Foreign Application Priority Data
Feb. 25, 2004 (JP) 2004-50203

(51) Int. Cl. G01R 27/26

(52) U.S. Cl. 324/662

(57) ABSTRACT

A rotation angle sensor including a variable capacitor and a C-V converting circuit, wherein the variable capacitor has a detected object fastened and fixed to its shaft, a planar shape of a movable electrode is set so that an area of overlapping parts of electrodes changes linearly with respect to a change of the rotation angle of the movable electrode, a voltage signal of the C-V converting circuit corresponds to the change of the electrostatic capacity of the variable capacitor with respect to the fixed capacitor, and consequently the voltage signal of the C-V converting circuit (detection signal) can be made to change linearly with respect to broad changes of the rotation angle of the detected object (0° to 270°).

### BACKGROUND OF THE INVENTION

1. Field of the Invention

The present invention relates to a rotation angle sensor, more particularly relates to a rotation angle sensor for detecting the rotation angle of a detected object.

2. Description of the Related Art

In the past, wide use has been made of rotation angle sensors each provided with a magnet attached to an object for detection of the rotation angle and rotating along with the detected object and a Hall element arranged in a magnetic field generated by the magnet and outputting a voltage corresponding to the intensity of the magnetic field and each outputting to the outside an output voltage of the Hall element (Hall element) changing along with the angular change between a magnetic field direction of the magnet and a magnetosensitive surface of the Hall element as a signal showing the rotational angle of the detected object (for example, see Japanese Unexamined Patent Publication (Kokai) No. 2000-329513 (pages 2 to 10, FIG. 4 and FIG. 5). This rotation angle sensor is for example used for detection of the opening angle of a throttle valve of an automobile engine, a depression angle of an accelerator pedal, etc.

In a rotation angle sensor using a Hall element, due to the magnet rotating around the Hall element along with rotation of the detected object, the magnetic field direction of the magnet relative to the magnetosensitive surface of the Hall element changes and a detection signal corresponding to the changed angle (Hall voltage) is output from the Hall element. The detection signal of the Hall element changes sinusoidally with respect to the angular change of the detected object (magnet).

When desiring to make the detection signal (Hall voltage) change linearly with respect to the angular change of the detected object (magnet), it is sufficient to suitably set the dimensions and shape of the magnet and its mounted position so that the magnetic field direction changes linearly with respect to the magnetosensitive surface of the Hall element. However, in a rotation angle sensor using a Hall element, no matter how setting the dimensions and shape of the magnet and its mounting position, it is difficult to make the detection signal (Hall voltage) change linearly with respect to broad changes in the rotation angle of the detected object. Further, in recent years, it has been requested to change the detection signal to a desired voltage value for broad changes in the rotation angle of the detection object.

Further, a rotation angle sensor using a Hall element not only uses an expensive Hall element, but also is complicated in structure, so is high in manufacturing costs. Further, a rotation angle sensor using a Hall element is difficult to make more compact since it uses a magnet.

### SUMMARY OF THE INVENTION

An object of the present invention is to provide a compact, low cost rotation angle sensor able to change the detection signal to a desired voltage value for broad changes in the rotation angle of the detection object.

To attain the above object, according to a first aspect of the invention, there is provided a rotation angle sensor provided with a variable capacitor comprised of a movable electrode mounted and fixed to an object for detection of the rotation angle and a fixed electrode arranged in parallel with the movable electrode and a C-V converting circuit for converting an electrostatic capacity between electrodes of the variable capacitor to a voltage signal, wherein the fixed electrode is fixed regardless of rotation of the detected object, the movable electrode rotates along with rotation of the detected object, the C-V converting circuit converts the electrostatic capacity between electrodes, which changes along with the rotational angle of the movable electrode, to a voltage signal, and outputs the voltage signal as a detection signal showing the rotational angle of the detection object.

Since the movable electrode rotates along with rotation of the detection object, if setting the planar shapes of the electrodes so that the electrostatic capacity between the electrodes changes in accordance with the change in the rotation angle of the movable electrode, the C-V converting circuit can output a desired voltage signal corresponding to the rotation angle of the detection object (movable electrode) and can change the detection signal to the desired voltage value for broad changes of the rotation angle of the detection object.

Further, since no Hall element or magnet is used, the manufacturing cost can be kept low and the size can be reduced. Further, the variable capacitor can be easily fabricated using micromachining technology, while the C-V converting circuit can be configured by a semiconductor integrated circuit. Therefore, it is possible to provide a variable capacitor and C-V converting circuit integrated on a single IC and possible to reduce the size and reduce the cost of the rotation angle sensor.

Preferably, the planar shapes of the movable electrode and fixed electrode are set so that the electrostatic capacity between electrodes assumes a desired electrostatic capacity value with respect to changes in the rotation angle of the movable electrode.

Since the planar shapes of the electrodes are set so that the electrostatic capacity between electrodes assumes a desired electrostatic capacity value with respect to changes in the rotation angle of the movable electrode, the effects of the invention can be reliably obtained.

Preferably, the C-V converting circuit is comprised of an operational amplifier with an inverting input terminal connected to the variable capacitor and a switched capacitor circuit provided with a switch and feedback capacitor connected in parallel between the inverting input terminal and output terminal of the operational amplifier.

By using a C-V converting circuit comprised of a switched capacitor circuit, the effects of the invention can be reliably obtained.

More preferably, the electrostatic capacity between electrodes changes linearly with respect to changes in the rotation angle of the movable electrode, the planar shape of the movable electrode is a long strip shape, and the planar shape of the fixed electrode is a deformed teardrop shape or flatten semicircular shape.

### BRIEF DESCRIPTION OF THE DRAWINGS

These and other objects and features of the present invention will become clearer from the following description of the preferred embodiments given with reference to the attached drawings, wherein:

FIG. 1A is a plan view of the schematic configuration of a rotation angle sensor 10 of a first embodiment of the present invention, while FIG. 1B is a front view of a rotation angle sensor 10;

FIGS. 2A and 2B are front views for explaining the operation of the rotation angle sensor 10;

FIG. 3 is a graph of the relationship between the rotation angle of the movable electrode 14 and the electrostatic capacity between the electrodes 12 and 14 in the first embodiment;

FIGS. 4A and 4B are circuit diagrams of a C-V converting circuit 20 forming the rotation angle sensor 10;

FIG. 5 is a timing chart for explaining the operation of the C-V converting circuit 20;

FIG. 6A is a plan view of the schematic configuration of a rotation angle sensor 30 of a second embodiment of the present invention, while FIG. 6B is a front view of the rotation angle sensor 30; and

FIG. 7 is a graph of the relationship between the rotation angle of the movable electrode 14 and the electrostatic capacity between the electrodes 12 and 14 in the second embodiment.

### DESCRIPTION OF THE PREFERRED EMBODIMENTS

Preferred embodiments of the present invention will be described in detail below while referring to the attached figures. Common components in the embodiments are assigned the same notations.

### First Embodiment

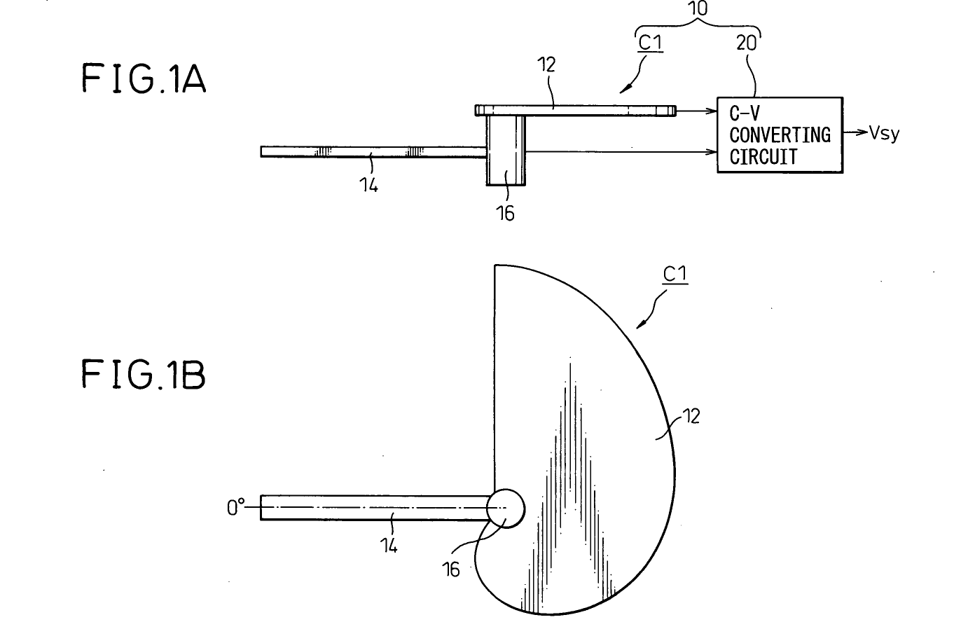

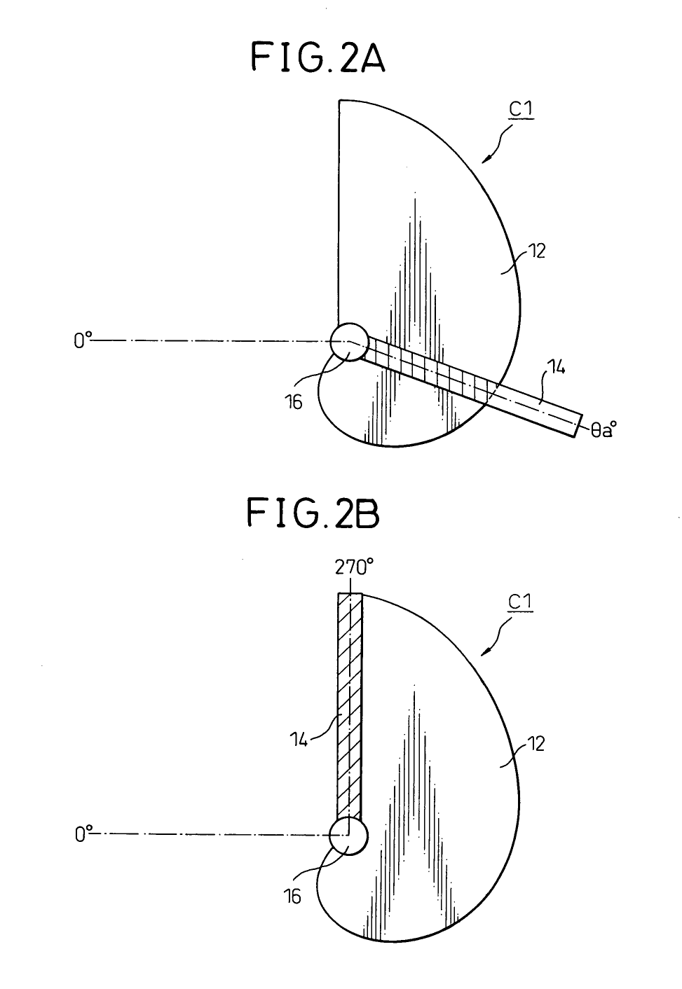

FIG. 1A is a plan view of the schematic configuration of a rotation angle sensor 10 of the first embodiment of the invention. FIG. 1B and FIGS. 2A and 2B are front views of the rotation angle sensor 10. The rotation angle sensor 10 is comprised of a variable capacitor C1 and a C-V (capacity-voltage) converting circuit 20.

Configuration and Operation of Variable Capacitor

The variable capacitor C1 is comprised of a fixed electrode 12, a movable electrode 14, and a shaft 16. Further, the variable capacitor C1 is prepared using micromachining technology. The external dimensions of the variable capacitor C1 are less than 1 mm vertically and horizontally as seen from the front direction shown in FIG. 1B and FIGS. 2A and 2B.

The planar fixed electrode 12 is rotatably provided with a cylindrical shaft 16 in a direction vertical to its surface. The shaft 16 has a long strip shaped movable electrode 14 fastened and fixed to it. Further, the movable electrode 14 and the shaft 16 are electrically connected, while the movable electrode 14 and shaft 16 is electrically insulated from the fixed electrode 12.

Further, the electrodes 12 and 14 formed by the conductive material are arranged in parallel with a predetermined distance therebetween. The fixed electrode 12 is fixed to the fixed upon member (not shown) without regard as to the rotation of the movable electrode 14. Therefore, if rotating the shaft 16, the movable electrode 14 rotates along with the shaft 16. Along with rotation of the movable electrode 14, the area of the overlapping parts of the electrodes 12 and 14 changes.

Further, the shaft 16 is fastened and fixed to the object for detection of the rotation angle (not shown) and rotates together with the detected object. Note that the detected object may for example be a throttle valve of an automobile engine or a shaft of an accelerator pedal. Further, the rotation angle sensor 10 is used for detection of the opening angle of the throttle valve, the depression angle of the accelerator pedal, etc.

When the rotational angle of the movable electrode 14 is 0 degree, the electrodes 12 and 14 do not overlap, so the area of the overlapping parts of the electrodes 12 and 14 is zero (FIG. 1B). Further, when the rotation angle of the movable electrode 14 is θa° of more than 0° but less than 270°, only part of the movable electrode 14 (illustrated hatched part) overlaps with the fixed electrode 12 (FIG. 2A). Further when the rotation angle of the movable electrode 14 is 270°, all of the movable electrode 14 (illustrated hatched part) overlaps with the fixed electrode 12 (FIG. 2B).

Further, the planar shape of the movable electrode 14 is set so that the area of the overlapping parts of the electrodes 12 and 14 changes linearly with respect to changes in the rotation angle of the movable electrode 14, that is, the rotation angle of the movable electrode 14 and the area of the overlapping parts of the electrodes 12 and 14 are in a positive proportional relationship.

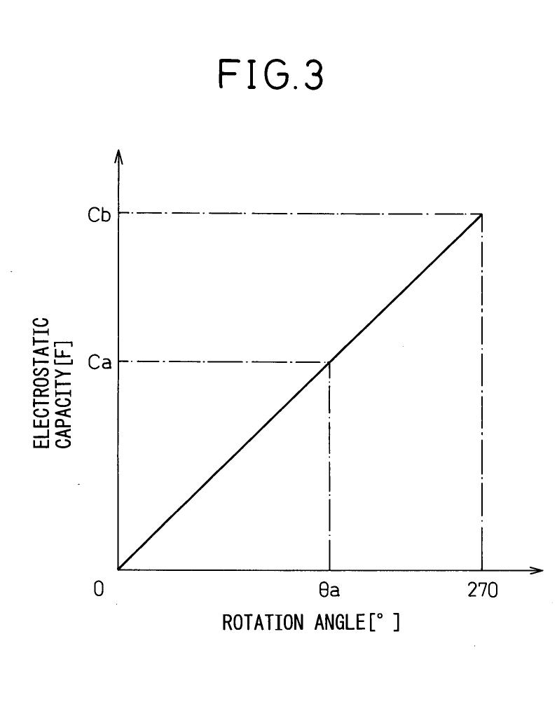

FIG. 3 is a graph of the relationship between the rotation angle of the movable electrode 14 and the electrostatic capacity between the electrodes 12 and 14 in the first embodiment. The area of the overlapping parts of the electrodes 12 and 14 and the electrostatic capacity between the electrodes 12 and 14 are in a positive proportional relationship. Therefore, the rotation angle of the movable electrode 14 and the electrostatic capacity between the electrodes 12 and 14 are in a positive proportional relationship.

In the example shown in FIG. 3, the value of the electrostatic capacity between the electrodes 12 and 14 when the rotation angle of the movable electrode 14 is 0° is zero, the value of the electrostatic capacity when the rotation angle is θa° is “Ca”, and the value of the electrostatic capacity when the rotation angle is 270° is “Cb”. As explained above, when setting the external dimensions of the variable capacitor C1 to about 1 mm vertically and horizontally as seen from the front direction, the electrostatic capacity Cb becomes 10e⁻¹⁵ (F).

Configuration and Operation of C-V Converting Circuit

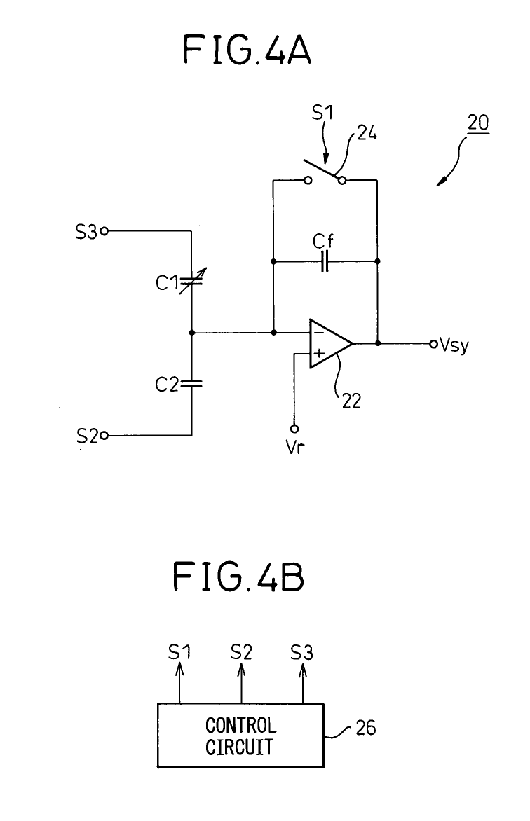

FIGS. 4A and 4B are circuit diagrams of the C-V converting circuit 20. The C-V converting circuit 20 is comprised of a switched capacitor circuit provided with a fixed capacitor C2, a feedback capacitor (feedback capacity element) Cf, an operational amplifier 22, a switch 24, and a control circuit 26.

The control circuit 26 (FIG. 4B) produces and outputs a control signal S1 for controlling the switch 24 and control signals S2 and S3 for controlling the capacitors C1 and C2. The variable capacitor (sensor capacity element) C1 and fixed capacitor (fixed capacity element) C2 are connected in series, the control signal S3 is applied to the variable capacitor C1, and the control signal S2 is applied to the fixed capacitor C2. Further, the control signals S2 and S3 are carrier waves with opposite phases.

The capacitors C1 and C2 form an electrostatic type sensor. That is, the variable capacitor C1 changes in electrostatic capacity in accordance with the rotational angle of the shaft 16 (detected object). Further, the fixed capacitor C2 functions as a reference capacity for finding the difference in capacity with the variable capacitor C1. Accordingly, if detecting the change of the capacity difference between the capacitors C1 and C2, the change of the rotation angle of the shaft 16 (detected object) can also be detected.

The inverting input terminal of the operational amplifier 22 is connected to the connecting point of the capacitors C1 and C2. The non-inverting input terminal of the operational amplifier receives the reference voltage Vr (for example, 2.5V). The switch 24 and the capacitor Cf are connected in parallel between the non-inverting input terminal and output terminal of the operational amplifier 22. The switch 24 is comprised of a switching element (for example, a bipolar transistor, FET, etc.) and is switched on/off by the control signal S1.

Further, the C-V converting circuit 20 converts the change in the difference in capacity of the capacitors C1 and C2 occurring along with the inversion of the control signals S2 and S3 comprised of the opposite phase carrier waves to a voltage signal (detection signal) Vsy and outputs it as Vsy from the output terminal of the operational amplifier 22.

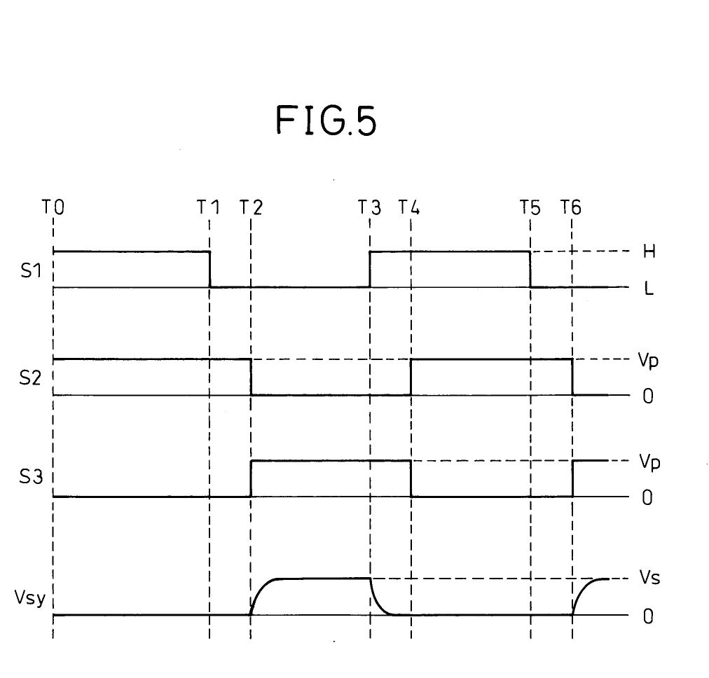

FIG. 5 is a timing chart for explaining the operation of the C-V converting circuit 20.

Below, the electrostatic capacities of the capacitors C1 and C2 and the capacitor Cf are indicated as “C1”, “C2”, and “Cf”. Further, the charges stored in the capacitors C1 and C2 and the capacitor Cf are indicated as “Q1”, “Q2”, and “Qf”. In addition, the control signals S2 and S3 assume two voltage values of a high level voltage Vp (for example, 5V) and a low level voltage (=0V). The voltage amplitude is Vp (V). The switch 24 is closed (turned on) by the high (H) level control signal S1, and is opened (turned off) by the low (L) level control signal S1.

At the time T0, the capacitors C1, C2 store the charges Q1 (=C1×(0−Vr)) and Q2 (=C2×(Vp−Vr)). Therefore, they together store the total charge Qt (=Q1+Q2) combining the charges Q1 and Q2.

At the time T1, the switch 24 is opened in accordance with the control signal S1, so the inverting-input terminal and output terminal of the operational amplifier 22 become open in terms of DC.

At the time T2, the capacitors C1, C2 store the charges Q1 (=C1×(Vp−Vr)) and Q2 (=C2×(0−Vr)). Therefore, they together store the total charge Qt′ (=Q1+Q2) combining the charges Q1 and Q2.

At this time, since the switch 24 is opened and the inverting-input terminal and output terminal of the operational amplifier 22 become open in terms of DC, the capacitor Cf stores the charge Qf (=Qt−Qt′). Therefore, the voltage signal Vsy of the output terminal of the operational amplifier 22 stabilizes at the charge Qf of the capacitor Cf divided by the electrostatic capacity Cf (Qf/Cf).

At the time T3, the switch 24 is closed in accordance with the control signal S1 and the inverting input terminal and output terminal of the operational amplifier 22 are short-circuited in terms of DC (voltage-follower state), the charge stored in the capacitor Cf is discharged, and the potential of the inverting input terminal of the operational amplifier 22 becomes the same potential as the reference voltage Vr.

Further, at the subsequent times T4 to T6, a similar operation is repeated. Therefore, the voltage signal Vsy of the output terminal of the operational amplifier 22 becomes a rectangular wave having the maximum voltage Vs (V) expressed by formula 1 as its amplitude:
Vs=Vp×(C1−C2)/Cf (1)

Action and Effect of First Embodiment

In the first embodiment explained in detail below, the variable capacitor C1 and C-V converting circuit 20 form the rotation angle sensor 10. Further, the shaft 16 of the movable electrode 14 forming the variable capacitor C1 has the detected object fastened and fixed to it. Further, the planar shape of the movable electrode 14 is set so that the electrostatic capacity between the electrodes 12 and 14 changes linearly with respect to changes of the rotation angle of the movable electrode 14. Further, the output voltage signal Vsy of the C-V converting circuit 20 corresponds to the change of the electrostatic capacity of the variable capacitor C1 with respect to the fixed capacitor C2.

Therefore, according to the first embodiment, it is possible to make the voltage signal (detection signal) Vsy of the C-V converting circuit 20 change linearly with respect to broad changes (0° to 270°) of the rotation angle of the detected object (shaft 16). Further, the rotation angle sensor 10 does not use any Hall element or magnet, so is low in manufacturing cost and can be easily reduced in size.

Further, the variable capacitor C1 can be easily fabricated using micromachining technology. Therefore, the C-V converting circuit 20 can be configured by a semiconductor integrated circuit. Accordingly, it is possible to provide a variable capacitor C1 and C-V converting circuit 20 integrated on a single integrated circuit and possible to reduce the size and reduce the cost of the rotation angle sensor 10.

In the past, variable capacitors using semicircular movable electrodes and fixed electrodes have been widely used in electronic circuits. However, with variable capacitors using semicircular movable electrodes and fixed electrodes, it is only possible to change the rotation angle of the movable electrode in the narrow range of 0° to 180°. In addition, it is not possible to make the electrostatic capacity between the electrodes linearly change. Further, conventional variable capacitors have only used semicircular movable electrodes and fixed electrodes. A person skilled in the art could not easily have conceived of a variable capacitor C1 of the first embodiment from a conventional variable capacitor. That is, the variable capacitor C1 of the first embodiment is completely novel and had not been thought of in the past.

### Second Embodiment

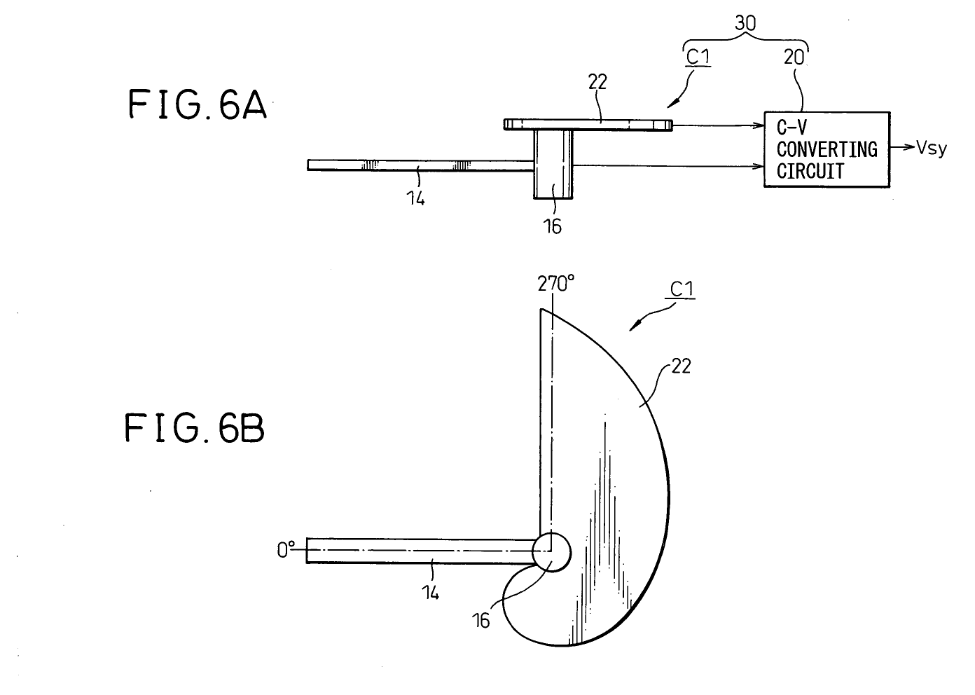

FIG. 6A is a plan view of the schematic configuration of a rotation angle sensor 30 of the second embodiment, while FIG. 6B is a front view of a rotation angle sensor 30. The rotation angle sensor 30 differs from the rotation angle sensor 10 of the first embodiment in only the planar shape of the fixed electrode 22 of the variable capacitor C1.

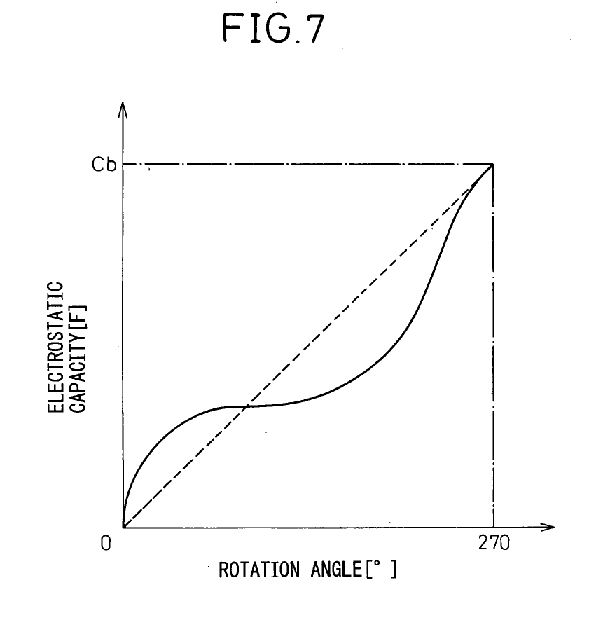

FIG. 7 is a graph of the relationship between the rotation angle of the movable electrode 14 and the electrostatic capacity between the electrodes 12 and 14 in the second embodiment. The planar shape of the fixed electrode 22 is set so that the electrostatic capacity between the electrodes 12 and 14 (area of overlapping parts of electrodes 12 and 14) changes by the characteristic shown in FIG. 7.

In this way, in the second embodiment, by suitably setting the planar shape of the fixed electrode 22, it becomes possible to change the electrostatic capacity between the electrodes 12 and 14 to a desired electrostatic capacity for broad changes of the rotation angle of the movable electrode 14 (0° to 270°). Further, the planar shape of the fixed electrode 22 may be set by conducting experiments investigating the electrostatic capacity between the electrodes 12 and 14 while changing the rotation angle of the movable electrode 14. Therefore, according to the second embodiment, it is possible to change the output voltage signal (detection signal) Vsy of the C-V converting circuit 20 to the desired voltage value for broad changes of the rotation angle of the detected object (shaft 16) (0° to 270°).

### Other Embodiments

However, the present invention is not limited to the above embodiments and may be embodied as explained below as well. In this case, actions and effects equal to or better than those of the above embodiments can be obtained.

(1) In the above embodiments, the movable electrode 14 was made a long strip shape, but if enabling the electrostatic capacity between the electrodes 12 and 14 to be changed to a desired value for the angular change of the movable electrode 14, it is possible to make the movable electrode 14 any planar shape in accordance with the planar shape of the fixed electrode 12 (22).

(2) In the above embodiments, the electrostatic capacity between the electrodes 12 and 14 was made changeable in the range of an angular change of the movable electrode 14 of 0° to 270°. However, by suitably setting the planar shapes of the electrodes 12 and 14 (for example, setting the width of the long strip shaped movable electrode 14 narrower), it is possible to make the electrostatic capacity between the electrodes 12 and 14 changeable in the range of 0° to about 360°.

(3) In the above embodiments, the planar shapes of the electrodes 12 and 14 are set so that the electrodes 12 and 14 do not overlap, that is, the electrostatic capacity between the electrodes 12 and 14 becomes zero, when the rotation angle of the movable electrode 14 is 0°. However, it is also possible to set the planar shapes of the electrodes 12 and 14 so that the electrodes 12 and 14 overlap and the electrostatic capacity between the electrodes 12 and 14 becomes a predetermined value when the rotation angle of the movable electrode 14 is 0°.

(4) In the above embodiments, it is also possible to eliminate the fixed capacitor C2 from the C-V converting circuit 20. Further, the C-V converting circuit 20 is not limited to a switched capacitor circuit and may be replaced by any circuit type C-V converting circuit.

(5) In the above embodiments, if sandwiching a dielectric between the electrodes 12 and 14 of the variable capacitor C1, it is possible to raise the electrostatic capacity between the electrodes 12 and 14 in accordance with the dielectric constant of the dielectric.

While the invention has been described with reference to specific embodiments chosen for purpose of illustration, it should be apparent that numerous modifications could be made thereto by those skilled in the art without departing from the basic concept and scope of the invention.

1. A rotation angle sensor provided with:
a variable capacitor comprised of a movable electrode mounted and fixed to an object for detection of the rotation angle and a fixed electrode arranged in parallel with the movable electrode and
a C-V converting circuit for converting an electrostatic capacity between electrodes of the variable capacitor to a voltage signal, wherein
the fixed electrode is fixed regardless of rotation of the detected object,
the movable electrode rotates along with rotation of the detected object,
the C-V converting circuit converts the electrostatic capacity between electrodes, which changes along with the rotational angle of the movable electrode, to a voltage signal, and outputs the voltage signal as a detection signal showing the rotational angle of the detection object.

2. A rotation angle sensor as set forth in claim 1, wherein the planar shapes of the movable electrode and fixed electrode are set so that the electrostatic capacity between electrodes assumes a desired electrostatic capacity value with respect to changes in the rotation angle of the movable electrode.

3. A rotation angle sensor as set forth in claim 1 or 2, wherein the C-V converting circuit is comprised of an operational amplifier with an inverting input terminal connected to the variable capacitor and a switched capacitor circuit provided with a switch and feedback capacitor connected in parallel between the inverting input terminal and output terminal of the operational amplifier.

4. A rotation angle sensor as set forth in claim 2, wherein the electrostatic capacity between electrodes changes linearly with respect to changes in the rotation angle of the movable electrode.

5. A rotation angle sensor as set forth in claim 2, wherein the planar shape of the movable electrode is a long strip shape.

6. A rotation angle sensor as set forth in claim 2, wherein the planar shape of the fixed electrode is a deformed teardrop shape or flatten semicircular shape.
